(19) United States
(12) Patent Application Publication
(10) Pub. No.: US 2010/0117626 A1
(43) Pub. Date: May 13, 2010

(54) ANALOG AND DIGITAL INDICATING METER

(75) Inventors: DAN WERTZ, Columbia, CT (US); SEAN LAVIN, Feeding Hills, MA (US); DAE KON YI, Springfield, MA (US); PAUL CAPPA, Enfield, CT (US); HENRY KUOK, East Longmeadow, MA (US)

Correspondence Address: MCCORMICK, PAULDING & HUBER LLP, CITY PLACE II, 185 ASYLUM STREET, HARTFORD, CT, 06103, US

(73) Assignee: GOVERNORS AMERICA CORPORATION, Agawam, MA (US)

(21) Appl. No.: 12/614,570

(22) Filed: Nov. 9, 2009

Related U.S. Application Data
(60) Provisional application No. 61/112,945, filed on Nov. 10, 2008.

(51) Int. Cl. G01R 13/00

(52) U.S. Cl. 324/140 R

(57) ABSTRACT

An analog and digital indicating electronic meter provides a digital readout of a measured value, and a pointer indication of the measured value on a selectable analog scale configured to match the measured value.

### CROSS REFERENCE TO RELATED APPLICATIONS

The present application claims priority to U.S. Provisional Patent Application 61/112,945 filed Nov. 10, 2008, and hereby incorporates herein by reference the disclosure thereof.

### FIELD OF THE INVENTION

The present invention relates to indication of measured or calculated values and, more particularly, to meter displays.

### BACKGROUND OF THE INVENTION

Needle indicating analog meters have been known for a long time. Referring to FIGS. 1-3, a typical needle indicating analog meter 2 can be configured to display a single measured value within a fixed range of values. The configuration of the needle indicating analog meter includes selection of mechanical and/or electrical components 4 for driving the needle pointer 6, and selection of a printed or engraved scale placard 8 for the pointer to move across. The printed or engraved scale placard is usable for displaying only a single measured value. When a complex system presents multiple measured values that need to be displayed, providing separate physical connections for each analog meter imposes costs for the meter materials, as well as indirect costs for system design constraints imposed by the multiple meters. Accordingly, there is a need for improvement in the art of meters providing analog displays.

Digitally indicating electronic meters are a more recent development. In a typical electronic sensing system, a sensor is provided at a measurement location. The sensor directly measures a measured value at that location. The sensor then transmits a measured value via electrical signals to a remotely-located electronic meter. The electronic meter typically displays the measured value by a digital readout. The digital readout displays the measured value with great precision and can be updated rapidly. Some digital readouts can be updated to display a sequence of measured values from different sensors. Each update of the digital readout involves a visible change or flicker of at least one numeral. The flicker caused by an update from, for example, 099.00 to 100.01 is not immediately discernible from the flicker caused by an update from, as another example, 100.00 to 000.01. Thus, monitoring multiple measured values via one or more digital readouts can lead to operator fatigue and distraction. Accordingly, there is a need for improvement in the art of electronic meters providing digital display of changing measured values.

### SUMMARY OF THE INVENTION

According to an embodiment of the present invention, an analog and digital indicating electronic meter includes a digital display configured to provide an analog scale and a digital readout of a measured value, and a pointer movably connected to the digital display for indicating the measured value on the analog scale. For example, the meter receives a plurality of measured values from a plurality of sensors, and updates the analog scale, the digital readout, and the pointer position to display a displayed value selected from the plurality of measured values.

According to another aspect of the present invention, the meter includes controls for selecting a displayed value from a plurality of measured values. Alternatively, the meter can automatically select a displayed value from the plurality of measured values. For example, the meter can select the displayed value by comparing the plurality of measured values to corresponding pluralities of ranges and/or setpoints.

According to another aspect of the present invention, the meter includes controls for selecting an appearance of the analog scale. For example, the meter can include controls for selecting an analog display scale and analog display units. Alternatively, the meter can automatically select an appearance of the analog scale matching a displayed value. For example, the meter can automatically select an analog display scale and analog display units matching a displayed value.

According to another aspect of the present invention, the meter includes controls for selecting warning output values. Alternatively, the meter can automatically select warning output values that match a displayed value.

According to another aspect of the present invention, the meter provides an indication when a displayed value exceeds a warning output value. For example, the meter provides flashing or color-changing illumination when the displayed value exceeds a warning output value.

According to another aspect of the present invention, the meter automatically selects an out-of-range measured value from a plurality of measured values, and displays the out-of-range measured value. Additionally, the meter can automatically display a sequence of other measured values related to the out-of-range measured value.

According to another aspect of the present invention, the meter displays a calculated value based on a combination of two or more measured values.

These and other objects, features and advantages of the present invention will become apparent in light of the detailed description of the best mode embodiment thereof, as illustrated in the accompanying drawings.

### BRIEF DESCRIPTION OF THE DRAWINGS

FIG. 1 is a front view of an analog display configured as a voltmeter.

FIG. 2 is a front view of an analog display configured as an ammeter.

FIG. 3 is a front view of an analog display configured as a microammeter.

FIG. 4 is a front partially cutaway view of an analog and digital indicating meter, according to a first embodiment of the present invention.

FIG. 5 is a front perspective view of a digital display, a pointer, and a pointer motor for use in the meter shown in FIG. 4.

FIG. 6 is a schematic illustration of the operation of the meter shown in FIGS. 4-6, including a visual output block.

FIG. 7 is a schematic illustration of a range/scale update loop within the visual output block shown in FIG. 6.

FIG. 8 is a schematic illustration of an analog pointer update loop within the visual output block shown in FIG. 6.

FIG. 9 is a schematic illustration of a digital value update loop within the visual output block shown in FIG. 6.

FIG. 10 is a schematic illustration of a warning output update loop within the visual output block shown in FIG. 6.

FIG. 11 is a front perspective view of a multi-mode analog and digital indicating meter, according to a second embodiment of the present invention.

FIG. 12 is a schematic illustration of the operation of the meter shown in FIG. 11.

FIG. 13 is a schematic illustration of an interface lookup table for use by an enhanced button driver implemented by a microprocessor of the meter shown in FIG. 11.

### DETAILED DESCRIPTION OF PREFERRED EMBODIMENTS

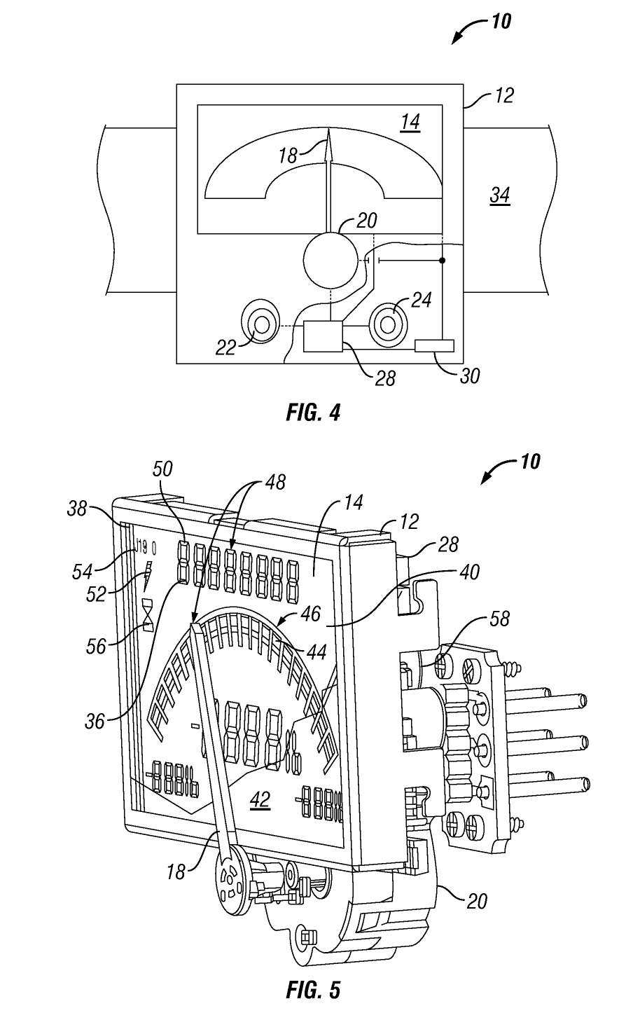

Referring to FIG. 4, according to a first embodiment of the present invention, an analog and digital indicating electronic meter 10 for displaying measured data includes a casing 12 that houses a digital display 14, a pointer 18 and an associated pointer motor 20, buttons 22 and 24, a microprocessor 28, and a power supply 30. The casing 12 can be mounted to a larger structure 34, such as a vehicle dashboard or a generator chassis. Alternatively, those of ordinary skill will appreciate that the meter can be incorporated into the larger structure, with various components of the meter being mounted directly to convenient parts of the larger structure.

Referring to FIG. 5, the digital display 14 is a segmented LCD (liquid crystal display) having a plurality of segments or pixels 36 that can separately be selectively activated. The digital display also could be an LED (light-emitting diode) display, an electronic ink panel, or any other sort of programmable, segmented or pixelated display. The digital display also can include one or more warning output indicators 38, for example colored LED illuminators or piezoelectric chirpers. Those of ordinary skill will appreciate that the warning output indicators can include a horn, a relay switch, or any other audible, visible, or electronic indicator.

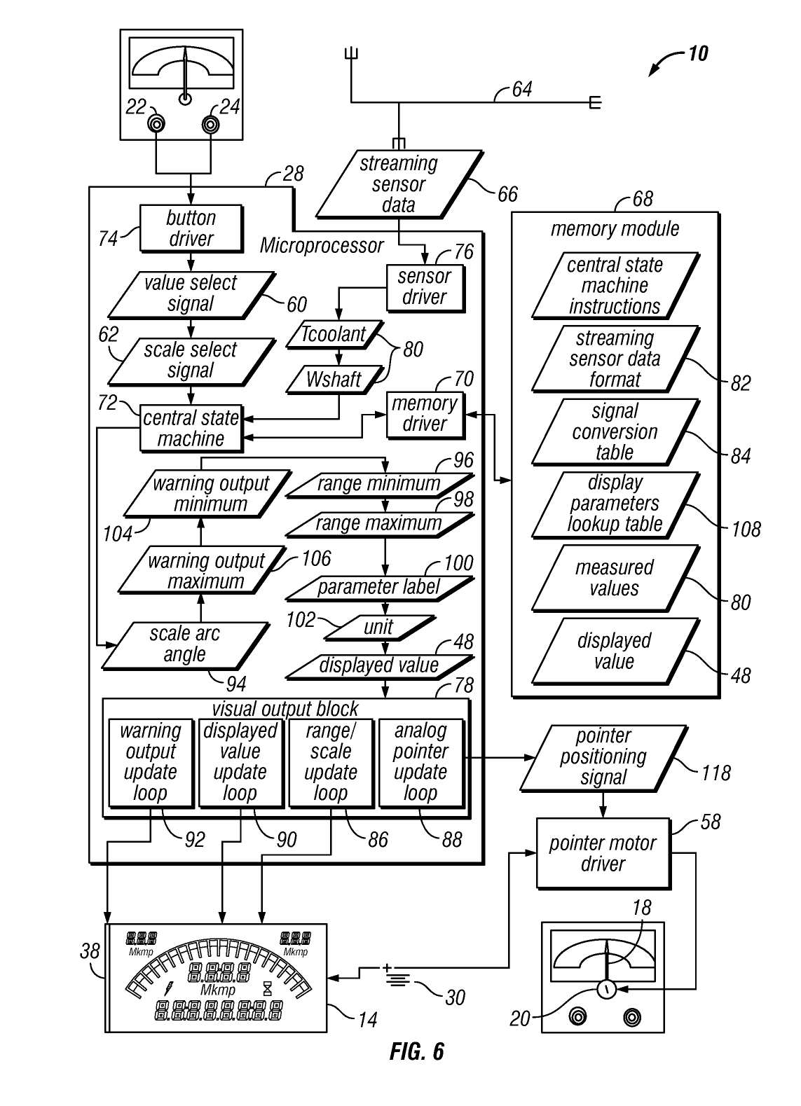

Typically, the pixels 36 of the digital display 14 are embedded into, or laminated onto, a reflective substrate 40 and are covered by a substantially transparent protective member 42. Some of the pixels of the digital display can be arranged in a curved shape, a linear shape, or any other shape conducive to forming segments 44 of an electronic analog scale 46 for indication of a displayed value 48 by the pointer 18. Other pixels of the digital display are arranged to provide a digital readout 50 for textual or numeric indication of the displayed value 48 and associated information such as a measurement unit and a sensor location. Some pixels also can be arranged to selectively provide a “lightning bolt” symbol 52, which displays that data is being received by the meter 10; a signal format validation symbol 54, which displays that the received data can be processed by the meter; and an hourglass symbol 56, which displays that the meter is “busy” and that the digital display displays older data. As further discussed below with reference to FIGS. 6-13, the digital display is controlled by the microprocessor 28 through conventional display driver circuitry incorporated into the digital display.

Still referring to FIG. 5, the pointer 18 is movably mechanically connected to the digital display 14 by way of the pointer motor 20. The pointer can be connected to the pointer motor via a geartrain. The microprocessor 28 controls the pointer motor, via conventional motor driver circuitry 58, to position the pointer along the electronic analog scale 46 for indicating the displayed value 48. The pointer motor can be a permanent magnet brushless DC micro-step motor, a rotary or linear variable differential transformer solenoid, or any equivalent electromechanical machine. Preferably, the pointer motor can maintain a fixed position during a momentary loss of power or interruption of control signal from the microprocessor. Preferably, the pointer motor driver 58 is configured for closed-loop control of the pointer position and is in communication with a rotary encoder or an equivalent device for detecting the position of the pointer. However, an open-loop control configuration also is acceptable for the pointer motor driver.

Referring to FIG. 6, the value-select button 22 and the scale-select button 24 are in communication with the microprocessor 28 to provide to the microprocessor a value select signal 60 and a scale select signal 62, respectively. Preferably, the buttons are configured as toggle switches, and the select signals are transient signals, where each push of a button causes a high-to-low or low-to-high DC voltage transient at a corresponding operator interface pin of the microprocessor. Alternatively, one or both of the value-select button and the scale-select button can be packaged with an associated motion encoder, so that twisting or deflecting the button will cause the associated motion encoder to produce a binary DC voltage waveform at an associated input of the microprocessor. As will be apparent to those of ordinary skill, other means can be provided for selecting a value and scale for display.

Still referring to FIG. 6, the microprocessor 28 is electrically connected to an electrical harness or data bus 64 that carries a streaming sensor data signal 66. Preferably, the streaming sensor data signal is a time-multiplexed digital signal. Alternatively, the streaming sensor data signal can be a code-multiplexed digital signal, or a sequence of analog signals. The microprocessor is in communication with the value-select button 22 and with the scale-select button 24 for receiving the value-select signal 60 and the scale-select signal 62. The microprocessor also is in communication with one or more conventional memory module(s) 68 via a conventional memory driver 70. The memory module(s) store instructions for configuring the microprocessor to implement a central state machine 72, and also store a variety of lookup tables for use by the central state machine, as further discussed below. The memory module(s) may include EEPROM (electronically-erasable-programmable read-only memory), RAM (random-access memory), and equivalent data storage structures. The microprocessor receives electrical power from the power supply 30.

In operation, the microprocessor 28 self-configures at startup by loading the central state machine instructions from the memory module 68. While configured as the central state machine 72, the microprocessor provides a button driver 74 for monitoring the value-select button 22 and the scale-select button 24, a sensor driver 76 for monitoring the streaming sensor data signal 66, and a visual output block 78 for controlling the digital display 14 and the pointer 18.

The button driver 74 monitors the value-select button 22 and the scale-select button 24 and produces the value-select signal 60 or the scale-select signal 62 based on actuation of the buttons. In one configuration of the digital meter shown in FIG. 4, the value-select button is pressably deflectable, and the button driver increments the value-select signal through a sequence of measured values to be displayed (for example, voltage, current, and temperature) each time the value-select button is pressed. Similarly, each time the scale-select button 24 is pressed, the button driver advances the scale-select signal through a sequence of analog scale ranges and resolutions (for example, 0-10V, 0-1V, 0-0.1V, 0-0.01V, 0-100V, 0-10V at hundred-increment resolution). In another configuration, the value-select button can be twisted, pressed, and/or moved like a joystick to advance through categories of sequences of measured values (for example, temperatures 1-6, pressures 1-8). Similarly, the scale-select button can be twisted to select a range center value and can be pushed to select a range scale (for example, twist to the right to increase the range center value, and press to step through a sequence of ranges and resolutions). One of ordinary skill will appreciate that in order to sense twisting and/or joystick movements of a button, one or more motion encoders or equivalent devices may need to be operatively connected with the button.

The sensor driver 76 monitors the streaming sensor data signal 66 and extracts one or measured values 80 based on the value select signal 60, according to a sensor data signal format 82 and a signal conversion lookup table or equivalent algorithm 84 stored in the memory module 68. Optionally, the signal conversion lookup table can be modified during operation of the meter, as further discussed below with reference to a second embodiment of the present invention. The streaming sensor data signal carries data from each sensor several times each second.

The visual output block 78 includes a range/scale update loop 86, an analog pointer update loop 88, a digital value update loop 90, and a warning output update loop 92. Each loop of the visual output block includes a delay of about one (1) second to several seconds to permit recognition of a displayed value by a user of the meter 10. Based on the value select signal 60 and on the scale select signal 62, the control state machine 72 provides to the visual output block a variety of display parameters including a scale arc angle 94, a range minimum and maximum 96, 98, the displayed value 48, a parameter label 100, a units label 102, and a warning output minimum and maximum 104, 106, according to a display parameters lookup table or equivalent algorithm 108. Optionally, the display parameters lookup table can be modified during operation of the meter, as further discussed below with reference to a second embodiment of the present invention. Based on the display parameters provided from the control state machine, the visual output block controls the digital display 14 and the pointer motor 20 to indicate the displayed value 48.

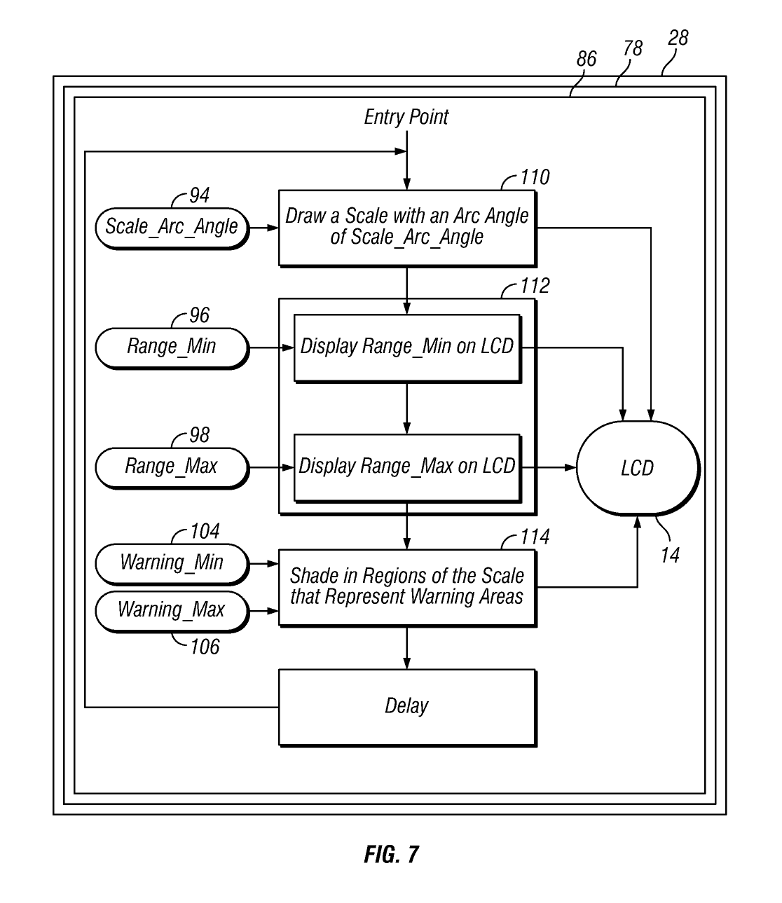

Referring to FIG. 7, the range/scale update loop 86 performs a step 110 of signaling the digital display 14 to show the electronic analog scale 46 with the scale arc angle 94, a step 112 of signaling the digital display to display the range minimum and maximum 96, 98, and a step 114 of signaling the digital display to shade warning regions of the scale outside the warning output minimum and maximum 104, 106.

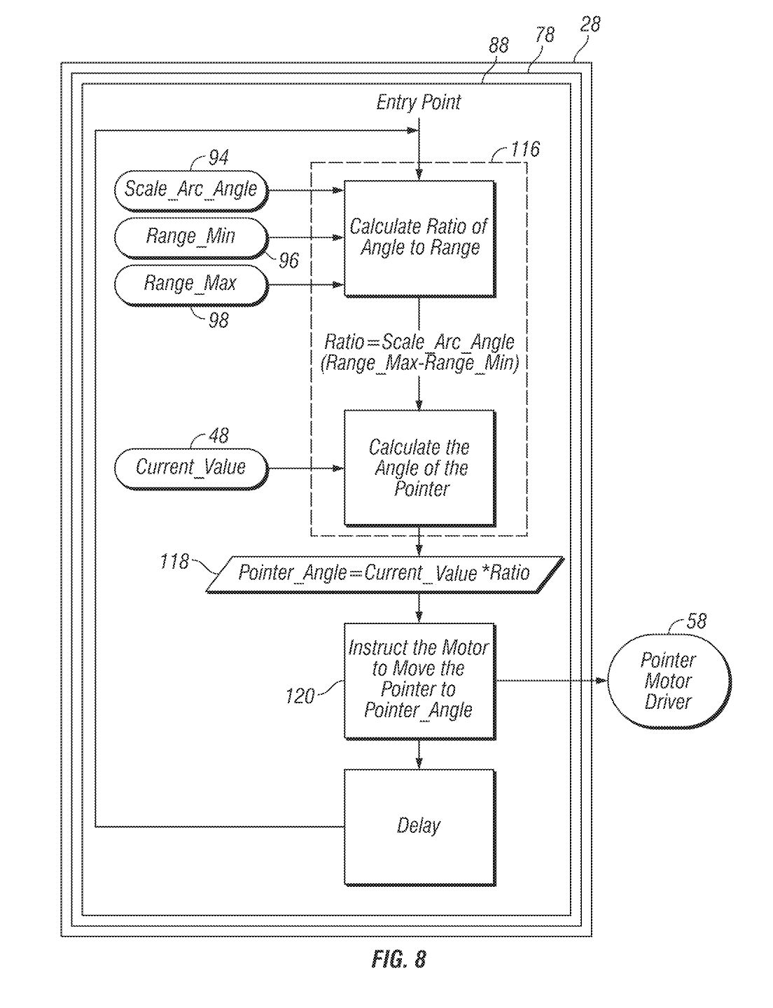

Referring to FIG. 8, the analog pointer update loop 88 performs a step 116 of determining a pointer-positioning signal 118 based on the scale arc range 94, the range minimum and maximum 96, 98, and the displayed value 48. The analog pointer update loop then performs a step 120 of controlling the pointer motor 20 according to the pointer-positioning signal.

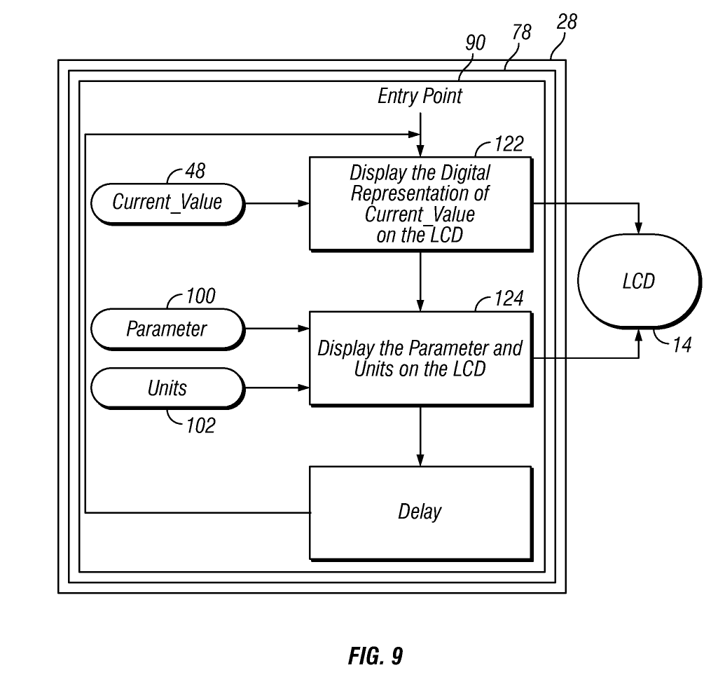

Referring to FIG. 9, the digital value update loop 90 performs a step 122 of signaling the digital display 14 to display the displayed value 48 and performs a step 124 of signaling the digital display to display the parameter label 100 and the units label 102.

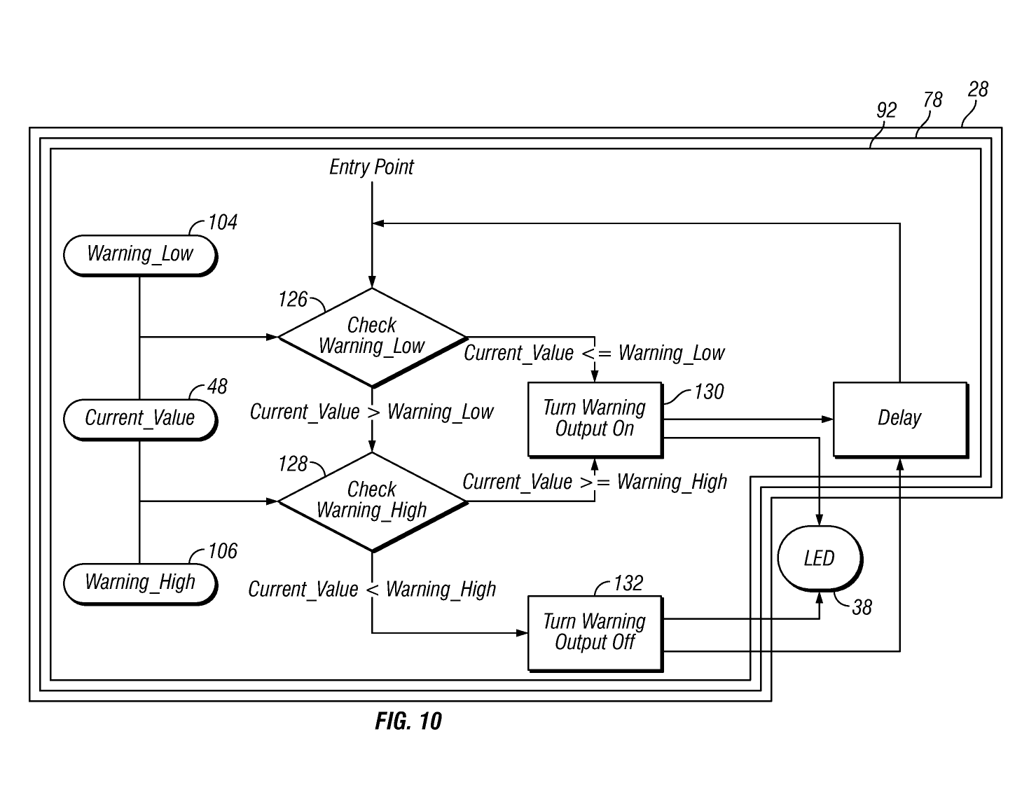

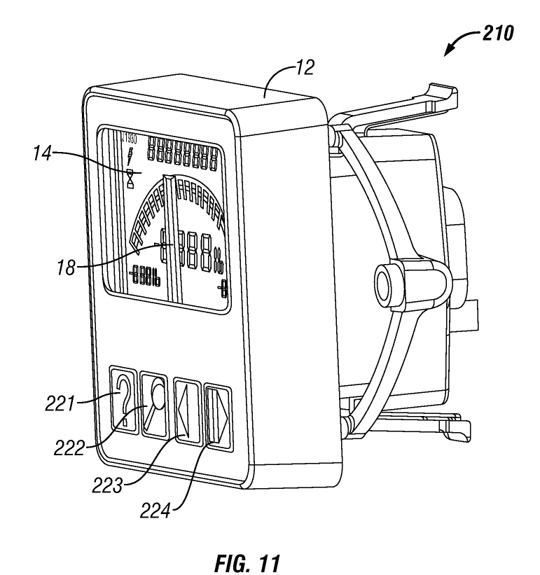

Referring to FIG. 10, the warning output update loop 92 performs a step 126 of comparing the displayed value 48 to the warning output minimum 104, and performs a step 128 of comparing the displayed value to the warning output maximum 106. Based on the comparisons, the warning output update loop performs either a step 130 of turning on the warning output indicators 38, or a step 132 of turning off the warning output indicators.

Referring back to FIGS. 4-7, the power supply 30 can be a dry cell battery, an alkaline battery, a solar cell, a vibratory generator, or any equivalent passive power source. In some configurations of the electronic meter 10, the power supply can be replaced by one or more electrical connections to a vehicle or system electrical bus (not shown).

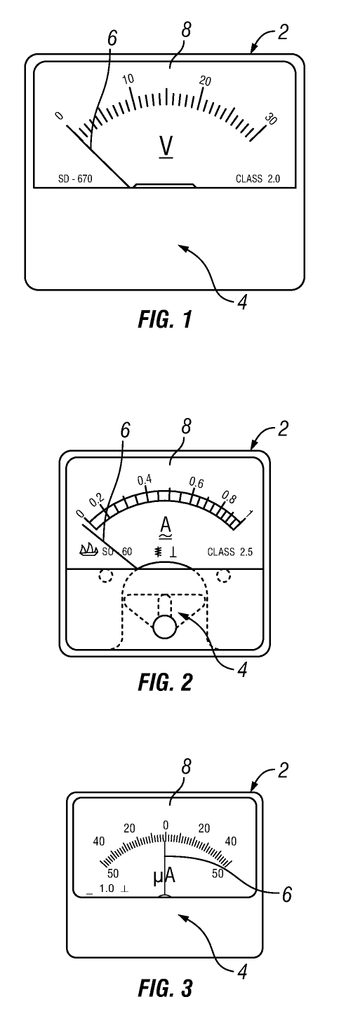

Referring to FIG. 11, like components are numbered alike to those shown in, and described with reference to, FIGS. 1-10. According to a second embodiment of the present invention, a multi-mode analog and digital indicating meter 210 includes a casing 12 that houses a digital display 14, a pointer 18 and an associated pointer motor 20, a first interface button 221, a second interface button 222, a third interface button 223, a fourth interface button 224, a microprocessor 28, one or more power supplies 30, and a conventional memory module 68 in communication with the microprocessor for storing lookup tables and central state machine instructions 272 including an enhanced button driver 274 and an enhanced visual output block 278. The first interface button 221 is displayed by a question mark or “help” symbol. The second interface button 222 is displayed by a magnifying glass or “zoom” symbol. The third interface button 223 is displayed by a left arrow or “previous” symbol. The fourth interface button 224 is displayed by a right arrow or “next” symbol. The symbols shown in FIG. 11 are chosen for ease of explanation; any other symbols can be used to label the interface buttons.

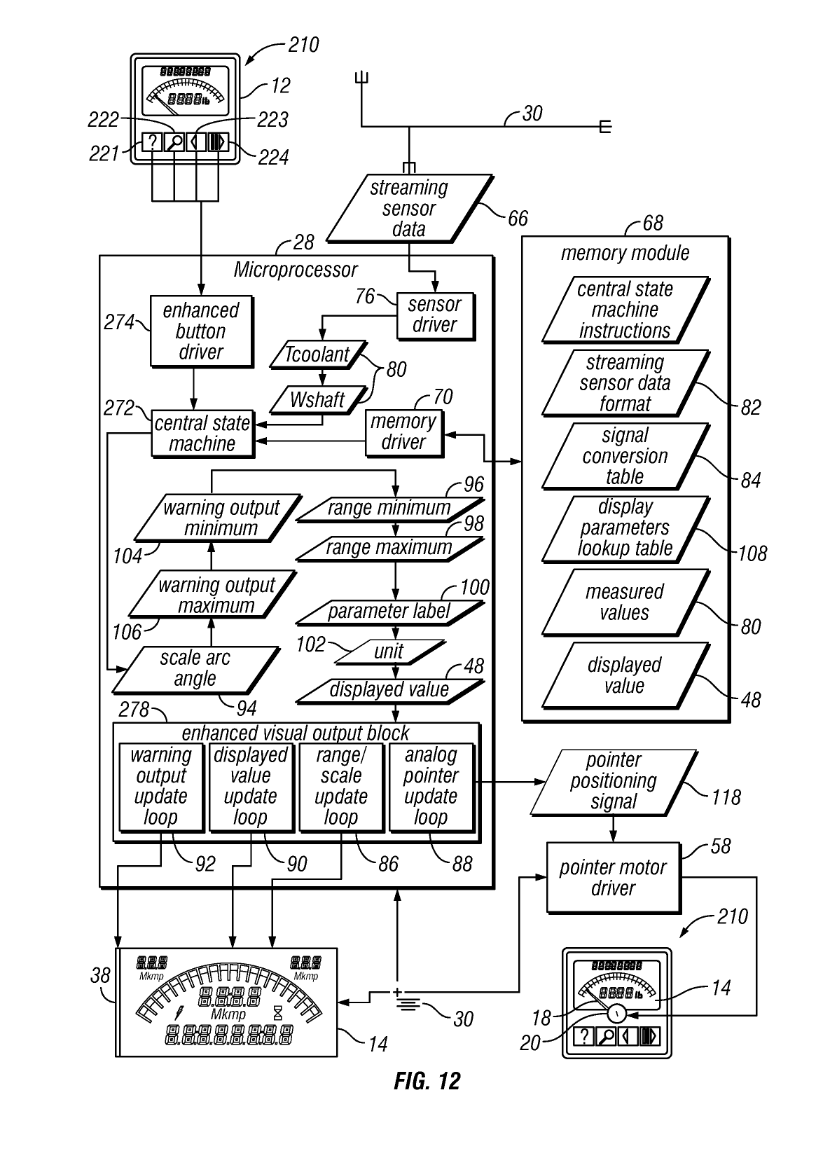

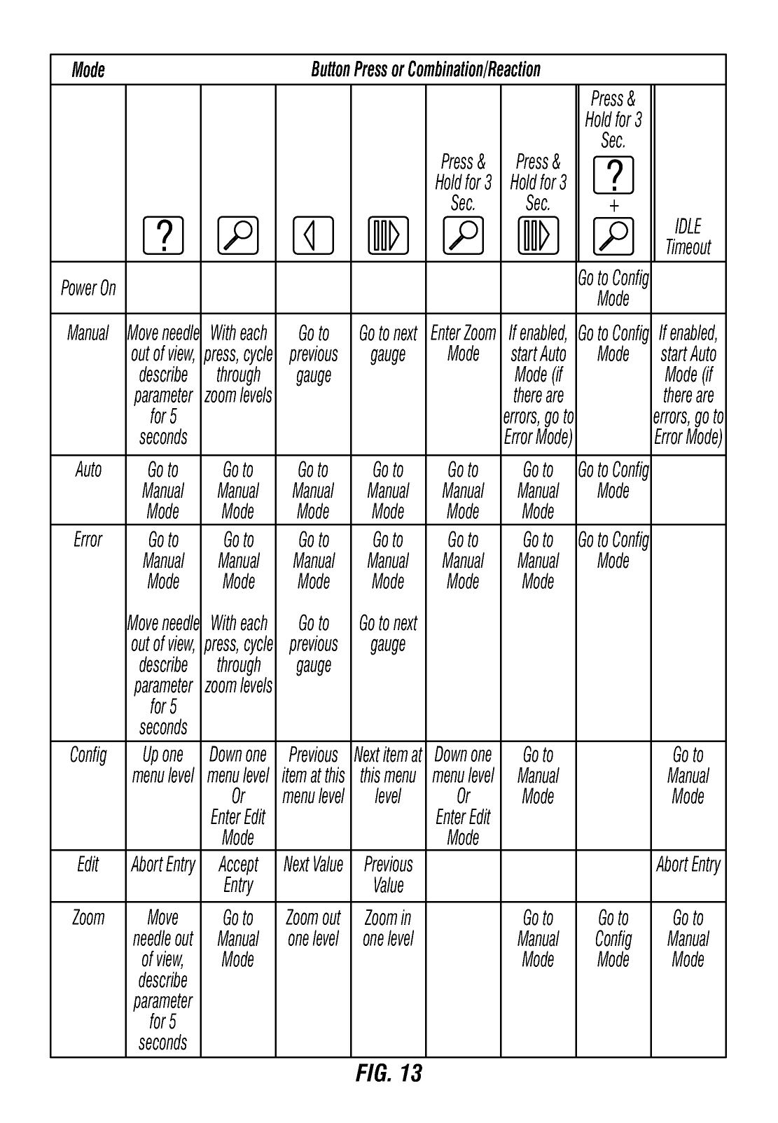

Referring to FIGS. 12 and 13, the enhanced button driver 274 is configured to monitor the interface buttons 221-224, to produce control signals based on actuation of the interface buttons, and to send the control signals to the central state machine 272. The control signals include the value select signal 60 and the scale select signal 62, as well as an operation mode select signal for setting an operation mode of the central state machine.

The operation mode of the central machine can be set to any one of an auto mode, a manual mode, an error mode, a config mode, an edit mode, and a zoom mode. At startup, the central state machine defaults to auto mode.

In auto mode, the central state machine 272 continuously monitors the streaming sensor data signal 66, periodically extracts each measured value 80, stores each measured value in the memory module 68, compares each measured value to corresponding warning outputs minima and maxima 104, 106, and periodically updates the displayed value 48 that is sent to the enhanced visual output block 278. At each update of the displayed value, the central state machine also updates the associated display data such as the range minimum and maximum 96, 98, so that over a period of time the digital display 14 and the pointer 18 indicate each of the measured values in the streaming sensor data signal, while the electronic analog scale 46 dynamically zooms to match the displayed value 48.

For readability, each measured value is stored in the memory module and is then displayed for a period corresponding to the loop delays of the visual output block 78. Optionally, the sequence of displayed values also can include calculated values 248 derived from data in the streaming sensor data signal. For example, if the streaming sensor data included a crankshaft strain measurement and a crankshaft angular speed measurement, the microprocessor could be configured to calculate an instantaneous horsepower value based on those measured values, as further discussed below with reference to the edit mode.

In auto mode, the central state machine responds to a combined three (3) second press of the “help” and “zoom” buttons by switching to config mode. Pressing any other button or combination of buttons switches the central state machine to manual mode.

In manual mode, the central state machine 272 continuously monitors the streaming sensor data signal 66, periodically extracts each measured value 80, stores each measured value in the memory module 68, and compares each measured value to corresponding warning outputs minima and maxima 104, 106, but sends to the enhanced visual display block 278 only a single displayed value 48, and corresponding parameter label and units label 100, 102, selected according to the value select signal 60. The central state machine also sends to the visual display block a scale arc range 94 and a range minimum and maximum 96, 98 based on the value select signal and on the scale select signal 62. Pressing the “previous” button decrements the value select signal, while pressing the “next” button increments the value select signal. Pressing the “zoom” button cycles through values of the range minimum and maximum obtained from the display parameters lookup table 154.

The central state machine 272 can automatically enter the error mode from the manual or auto mode when any of the measured values 80 exceeds a warning output minimum or maximum corresponding to that measured value. In the error mode, the central state machine automatically selects for display the measured value that exceeds the warning output minimum or maximum. In some embodiments of the invention, the central state machine can be configured to enter the error mode only if a measured value exceeds the corresponding warning output setpoint during more than a predetermined number of visual output block loop delays. The central state machine can also be configured to activated the warning indicators 38 while in the error mode. For example, a yellow LED warning indicator can be activated to provide a visible change in display backlighting color when the measured value closely exceeds the warning output minimum or maximum. A red LED warning indicator can be activated to provide a further change in backlighting when the measured value further exceeds the warning output minimum or maximum. The warning indicator also can be intermittently activated to provide flashing color changes, and the periodicity of color changes can be varied according to the severity of a measured value out-of-range condition.

In the config mode, the central state machine 272 sends menu parameters to the enhanced visual output block 278. The enhanced visual output block then controls the digital display 14 to provide menus for adjusting the streaming sensor signal format and the signal conversion lookup table. In the edit mode, the central state machine sends edit menu parameters to the enhanced visual output block, which controls the digital display to provide menus for editing the various other lookup tables.

Although this invention has been shown and described with respect to the detailed embodiments thereof, it will be understood by those skilled in the art that various changes in form and detail thereof may be made without departing from the spirit and the scope of the invention. For example, any of the various loops, modules, and drivers may be implemented as software or as analog or digital circuitry separate from or integrated into the microprocessor 28. Similarly, the functions described as being performed by the microprocessor can be separately implemented by discrete components or can be incorporated into more comprehensive software embodied in a digital or analog structure performing functions additional to the functions of the meter 10. The streaming data signal may be provided to the meter 10 from an external multiplexer, or can be produced within the meter by combining a plurality of signals separately received from a plurality of sensors. Other variations will be apparent to those skilled in the art.

What is claimed is:

1. An analog and digital indicating electronic meter comprising:
a digital display configured to provide an analog scale and a digital readout of a measured value;
a pointer movably connected to the digital display for indicating the measured value on the analog scale; and
a microprocessor operatively connected to control the digital display and the pointer for indicating the measured value.

2. The meter according to claim 1, wherein the meter is configured to receive a plurality of measured values from a plurality of sensors, and to update the digital readout, the analog scale, and the pointer position to indicate a displayed value selected from the plurality of measured values.

3. The meter according to claim 1, wherein the meter includes controls for selecting a displayed value from a plurality of measured values.

4. The meter according to claim 1, wherein the meter is configured to automatically select a sequence of displayed values from the plurality of measured values.

5. The meter according to claim 4, wherein the meter is configured to automatically select the displayed value by comparing each of the plurality of measured values to one or more corresponding warning output setpoints.

6. The meter according to claim 1, wherein the meter includes controls for selecting an appearance of the analog scale.

7. The meter according to claim 6, wherein the meter includes controls for selecting an analog display scale and analog display units.

8. The meter according to claim 1, wherein the meter is configured to automatically select an appearance of the analog scale matching a displayed value.

9. The meter according to claim 8, wherein the meter is configured to automatically select an analog display scale and analog display units matching a displayed value.

10. The meter according to claim 1, wherein the meter includes controls for selecting warning output values.

11. The meter according to claim 1, wherein the meter is configured to automatically select warning output values corresponding to a displayed value.

12. The meter according to claim 1, wherein the meter is configured to provide a warning output when a displayed value exceeds a warning output value.

13. The meter according to claim 12, wherein the meter is configured to provide flashing or color-changing illumination when the displayed value exceeds a warning output value.

14. The meter according to claim 1, wherein the meter is configured to automatically select an out-of-range measured value from a plurality of measured values.

15. The meter according to claim 14, wherein the meter is configured to automatically display a sequence of other measured values related to the out-of-range measured value.

16. The meter according to claim 14, wherein the meter is configured to automatically display the out-of-range measured value.

17. The meter according to claim 1, wherein the meter is configured to display a calculated value based on a combination of two or more measured values.

18. A method for configuring a single meter to provide analog and digital indication of any of a plurality of measured values, the method comprising:
configuring said single meter to select a measured value for display in response to actuation of controls provided in said meter;
configuring said single meter to selectably provide an analog scale appropriate to said measured value selected for display;
configuring said single meter to provide a digital readout of said measured value for display; and
configuring said single meter to move a pointer on said analog scale for indicating said measured value selected for display.
